(19) United States
(12) Patent Application Publication
(10) Pub. No.: US 2025/0176401 A1
(43) Pub. Date: May 29, 2025

(54) RESISTANCE MEASUREMENT TAG AND DISPLAY DEVICE INCLUDING THE SAME

(71) Applicant: SAMSUNG DISPLAY CO., LTD., YONGIN-SI (KR)

(72) Inventors: CHANGSUK LEE, Yongin-si (KR); SANG JIN LEE, Yongin-si (KR); CHONGSUP CHANG, Yongin-si (KR); Myoung Geun CHA, Yongin-si (KR)

(21) Appl. No.: 18/810,009

(22) Filed: Aug. 20, 2024

(30) Foreign Application Priority Data
Nov. 24, 2023 (KR) 10-2023-0165607

(51) Int. Cl. H10K 59/80; H10K 59/122

(52) U.S. Cl. CPC H10K 59/80522; H10K 59/122

(57) ABSTRACT

A tag for measuring resistance includes a substrate, an auxiliary electrode positioned on the substrate and having two portions spaced apart from each other with an opening therebetween, and a second electrode positioned within the opening, in which the auxiliary electrode includes a first layer and a second layer, the second layer is located between the first layer and the substrate, a portion of the first layer has an undercut structure, and does not overlap a top surface of the second layer, and the second electrode contacts the auxiliary electrode from a side of the auxiliary electrode.

### CROSS-REFERENCE TO RELATED APPLICATION

This application claims priority under 35 U.S.C. § 119 to Korean Patent Application No. 10-2023-0165607, filed on Nov. 24, 2023, in the Korean Intellectual Property Office, the entire contents of which are incorporated by reference herein.

### TECHNICAL FIELD

The present invention relates to a tag for measuring resistance and a display device including the same.

### DISCUSSION OF RELATED ART

The importance of display devices is gradually increasing along with the development of multimedia. For example, various display devices such as liquid crystal display (LCD) devices and light emitting diode (LED) display devices are being developed for visualizing multimedia information.

Among the display devices, light emitting display devices include light emitting devices that are self-emitting devices. The self-emitting devices do not require an additional external light source, so that the brightness and color can be controlled independently for each pixel, therefore capable of obtaining an infinite contrast ratio and producing true blacks and more vivid colors.

A light emitting device may include two opposing electrodes and a light emitting layer interposed therebetween. Electrons and holes provided from the two opposing electrodes recombine in the light-emitting layer to generate excitons, and the generated excitons change from an excited state to a ground state to emit light.

Since these light emitting display devices do not require a separate light source, they not only consume less power and can be configured to be lightweight and thin, but also have high-quality characteristics such as a wide viewing angle, high brightness and contrast, and fast response speed, therefore attracting significant attention as next-generation display devices.

### SUMMARY

Embodiments provide a resistance measurement tag that can measure the resistance between a second electrode (cathode) and an auxiliary electrode and a display device including the same.

A tag for measuring resistance according to an embodiment of the present invention includes a substrate, an auxiliary electrode located on the substrate and having two portions spaced apart from each other with an opening in between, and a second electrode located within the opening, in which the auxiliary electrode includes a first layer and a second layer, the second layer is located between the first layer and the substrate, some areas of the first layer have an undercut structure, and do not overlap a top surface of the second layer, and the second electrode contacts the auxiliary electrode from a side of the auxiliary electrode.

The two portions of the auxiliary electrode spaced apart from each other may be electrically connected by the second electrode.

The tag for measuring resistance may further include a partition wall located on the substrate, in which the partition wall may include an opening, and the second electrode may be located within the opening of the partition wall.

The partition wall includes a first layer and a second layer, the first layer of the partition wall is located between the second layer of the partition wall and the substrate, and a portion of the first layer of the partition wall may not overlap the second layer of the partition wall.

The tag for measuring resistance may further include a light emitting layer located between the substrate and the second electrode.

The tag for measuring resistance may further include a first electrode positioned between the substrate and the second electrode.

The second electrode may not contact the first layer of the auxiliary electrode.

A contact resistance between the second electrode and the auxiliary electrode may be measured on an upper surface of the auxiliary electrode.

A display device according to an embodiment of the present invention includes a substrate including a display area and a non-display area, and a resistance measurement tag located in the display area or the non-display area, in which the resistance measurement tag includes a first auxiliary electrode located on the substrate and having two portions spaced apart from each other with an opening in between, and a first second electrode located within the opening, in which the first auxiliary electrode includes a first layer and a second layer, the second layer is located between the first layer and the substrate, some areas of the first layer have an undercut structure, and do not overlap a top surface of the second layer, and the first second electrode is in contact with the first auxiliary electrode from a side of the first auxiliary electrode.

The display device further includes a plurality of pixels located in the display area, in which one second second electrode is located for each of the pixels, and two of the second second electrodes respectively located in two adjacent ones of the pixels may be electrically connected to each other through a second auxiliary electrode.

In the pixels located in the display area, each of the second second electrodes may be in contact with the second auxiliary electrode from a side of the second auxiliary electrode.

In the display area, the second auxiliary electrode includes a first layer and a second layer, the second layer is located between the first layer and the substrate, and a portion of the first layer has an undercut structure, and does not overlap a top surface the second layer.

In the pixels located in the display area, the second auxiliary electrode may include an opening for each of the pixels, and each of the second second electrodes may be located respectively within the opening for each of the pixels.

Each of the pixels located in the display area may further include a first encapsulation layer covering the opening, and each of the first encapsulation layers may be positioned separately for each of the pixels.

The two portions of the first auxiliary electrode spaced apart from each other of the resistance measurement tag may be electrically connected by the first second electrode.

The resistance measurement tag may further include a partition wall located on the substrate, the partition wall may include an opening, and the first second electrode may be located within the opening of the partition wall.

The partition wall of the resistance measurement tag includes a first layer and a second layer, the first layer is located between the second layer and the substrate, and a portion of the first layer does not overlap the second layer.

The resistance measurement tag may further include a light emitting layer located between the substrate and the first second electrode.

The resistance measurement tag may further include a first electrode positioned between the substrate and the first second electrode.

The first second electrode of the resistance measurement tag may not contact the first layer of the first auxiliary electrode.

According to embodiments of the present invention, a resistance measurement tag capable of measuring resistance between a cathode and an auxiliary electrode and a display device including the same are provided.

### BRIEF DESCRIPTION OF THE DRAWINGS

Embodiments of the present invention will be more clearly understood from the following detailed description taken in conjunction with the accompanying drawings in which:

FIG. 1 shows a display device according to an embodiment of the present invention;

FIG. 2 illustrates the plane of a pixel located in the display area DA of FIG. 1;

FIG. 3 is a cross-sectional view taken along line I-I′ of FIG. 2;

FIG. 4 shows the front of a tag for measuring resistance according to an embodiment of the present invention;

FIG. 5 is a cross-sectional view taken along line A-B of FIG. 4;

FIG. 6 shows a tag for measuring resistance according to an embodiment of the present invention;

FIG. 7 shows a tag for measuring resistance according to an embodiment of the present invention;

FIG. 8 shows a method of measuring contact resistance using a tag for measuring resistance according to an embodiment of the present invention;

FIG. 9 to FIG. 11 each shows a planar shape of a tag for measuring resistance according to an embodiment of the present invention; and

FIG. 12 to FIG. 23 show a method of manufacturing a tag for measuring resistance according to an embodiment of the present invention.

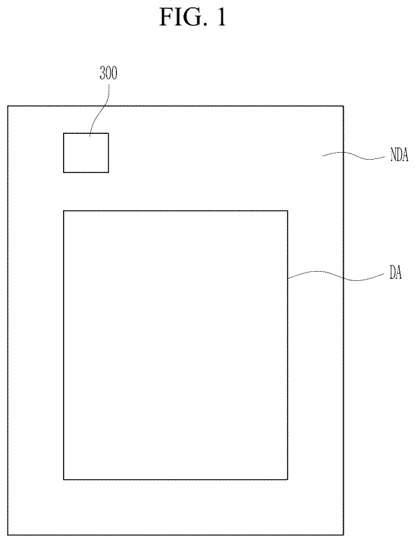

Since the drawings in FIGS. 1-23 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Hereinafter, with reference to the accompanying drawings, various embodiments of the present invention will be described in detail so that those skilled in the art can easily implement the present invention.

The present invention may be implemented in many different forms and is not limited to the embodiments described herein.

To clearly explain the present invention, parts that are not relevant to the description are omitted, and identical or similar components are assigned the same reference numerals throughout the specification.

When a part of a layer, membrane, region, or plate is said to be “above” or “on” another part, this includes not only cases where it is “directly above” another part, but also cases where there is another part in between.

Conversely, when a part is said to be “right on top” of another part, it means that there is no other part in between.

It will be understood that being “above” or “on” a reference part means being located above or below the reference part, and does not necessarily mean being located “above” or “on” it in the direction opposite to gravity. It will be understood that the spatially relative terms are intended to encompass different orientations of the device in use or in operation, in addition to the orientation depicted in the figures.

Throughout the specification, when a part is said to “include” a certain element, this means that it may further include other elements, rather than excluding other elements, unless specifically stated to the contrary.

Throughout the specification, when reference is made to “on a plane”, this means when the target portion is viewed from above, and when reference is made to “in a cross-section”, this means when a cross-section of the target portion is cut vertically and viewed from the side. Now, a tag for measuring resistance and a display device including the same according to an embodiment of the present invention will be described below with reference to the drawings.

FIG. 1 shows a display device according to an embodiment of the present invention.

Referring to FIG. 1, the display device according to an embodiment of the present invention may include a display area DA and a non-display area NDA.

As shown in FIG. 1, a resistance measurement tag 300, which is also referred to as a tag 300 for measuring resistance, may be located in the non-display area NDA. However, this is an example, and the tag 300 for measuring resistance may be located in the display area DA.

The present invention relates to a resistance measurement tag 300 for measuring contact resistance between a second electrode (cathode) and an auxiliary electrode of a pixel located in the display area DA. The resistance measurement tag 300 also includes at least a second electrode and an auxiliary electrode, and may be located in the non-display area NDA or in the display area DA.

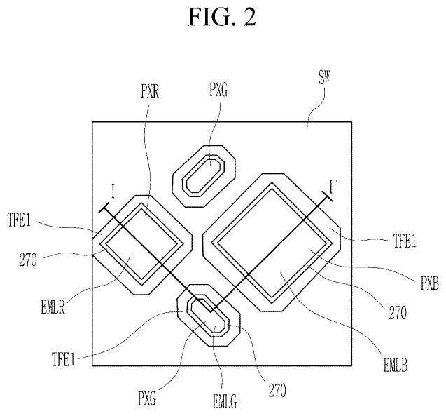

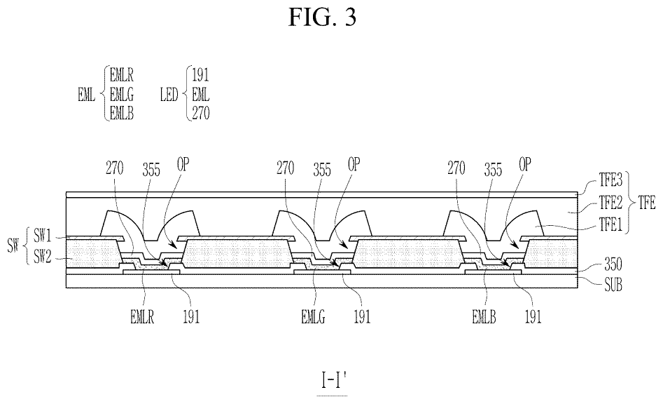

FIG. 2 illustrates the plane of a pixel located in the display area DA of FIG. 1. FIG. 3 is a cross-sectional view taken along line I-I′ of FIG. 2.

Referring to FIGS. 2 and 3, the display device according to an embodiment of the present invention includes a substrate SUB, a first electrode 191 positioned on the substrate, and a partition wall 350 positioned on the first electrode 191.

The first electrode 191 may be electrically connected to a transistor located on the substrate SUB. The transistor may be a driving transistor for driving a light emitting device LED to be described.

Referring to FIG. 3, a light emitting layer EML may be located in the opening 355 of the partition wall 350. The light emitting layer EML may include an organic light-emitting material or inorganic light-emitting material. For example, the light emitting layer EML may include a fluorescent or phosphorescent material. The light emitting layer EML may also include a quantum dot or a quantum rod as a light-emitting material. In addition, the light emitting layer EML may include an inorganic light-emitting material, which may include crystalline semiconductors such as, for example, gallium nitride (GaN), indium phosphide (InP), etc.

FIGS. 2 and 3 each illustrates red pixels PXR, green pixels PXG, and blue pixels PXB, and as shown in FIGS. 2 and 3, red light-emitting layers EMLR may provide red light in the red pixels PXR, green light-emitting layers EMLG may provide green light in the green pixels PXG, and blue light-emitting layers EMLB may provide blue light in the blue pixels PXB. However, this is only an example, and the present invention is not limited thereto.

Referring to FIG. 3, the auxiliary electrode SW may be located overlapping the partition wall 350.

The auxiliary electrode SW may include a first layer SW1 and a second layer SW2, and may have an opening OP that overlaps the opening 355 of the partition wall 350. The second layer SW2 may be located between the first layer SW1 and the partition wall 350. For example, the second layer SW2 may be located between the first layer SW1 and the substrate SUB.

As shown in FIG. 3, the edge of the first layer SW1 may have an undercut structure in the opening OP, and may protrude more than the edge of the second layer SW2. For example, some areas of the first layer SW1 may not overlap a top surface of the second layer SW2.

This will be explained separately later, but is a structure for forming second electrodes 270 within the openings OP of the auxiliary electrode SW.

Referring to FIG. 3, the second electrode 270 is located within the opening OP of the auxiliary electrode SW.

The second electrode 270 may be positioned within each opening OP of the auxiliary electrode SW. For example, the second electrode 270 may be formed in each of the openings formed in the red pixels PXR, the green pixels PXG, and the blue pixels PXB.

As shown in FIG. 3, the first electrode 191, the light emitting layer EML, and the second electrode 270 may form a light emitting device LED. Furthermore, the light emitting device LED may further include a hole transport region arranged between the first electrode 191 and the light emitting layer EML and an electron transport region arranged between the light emitting layer EML and the second electrode 270. The hole transport region may include at least one of a hole injection layer, a hole transport layer, or an electron blocking layer. The electron transport region may include at least one of an electron injection layer, an electron transport layer, or a hole blocking layer. However, the present invention is not limited thereto.

The second electrode 270 is in contact with the auxiliary electrode SW from the side. For example, the second electrode 270 is in contact with the side surface of the auxiliary electrode SW exposed to the opening OP of the auxiliary electrode SW. For example, a plurality of second electrodes 270 respectively located in a plurality of pixels are connected as one through the auxiliary electrode SW.

In an embodiment of the present invention, the shapes of the second electrodes 270 respectively for the red pixel PXR, the green pixel PXG, and the blue pixel PXB may be different from each other in a plan view.

In a typical display device, the second electrode 270 is located as a single plate over a plurality of pixels, but in the display device according to an embodiment of the present invention, the second electrode 270 is located separately for each pixel, and it has a structure in which two second electrodes 270 are connected as one through an auxiliary electrode SW. For example, two of the second electrodes 270 respectively located in two adjacent ones of the pixels are electrically connected to each other through an auxiliary electrode SW.

Therefore, the second electrode 270 of each pixel receives a driving voltage through the auxiliary electrode SW, and contact resistance between the second electrode 270 and the auxiliary electrode SW directly affects the luminance of the light emitting diode LED.

Therefore, in the display device having the structure shown in FIGS. 2 and 3, measuring the contact resistance between the second electrode 270 and the auxiliary electrode SW may be needed. However, due to the structure of the display device according to an embodiment of the present invention, it is not easy to measure the contact resistance between the second electrode 270 and the auxiliary electrode SW.

Referring again to FIG. 3, the encapsulation layer TFE is located on the second electrode 270. For example, the encapsulation layer TFE may be positioned over the second electrode 270 and the auxiliary electrode SW. The encapsulation layer TFE may cover the light emitting device LED to prevent the light emitting device LED from being damaged or degraded by external impurities.

The encapsulation layer TFE includes a first encapsulation layer TFE1 that covers the opening of the auxiliary electrode SW in each pixel, a second encapsulation layer TFE2, and a third encapsulation layer TFE3, located on the front of the display device.

As shown in FIG. 3, to form the light emitting layer of each pixel, the first encapsulation layer TFE1 covers the opening OP of the auxiliary electrode SW, and thus it is not easy to measure the contact resistance between the second electrode 270 and the auxiliary electrode SW. The contact resistance of the auxiliary electrode SW and the second electrode 270 can be measured on the two upper surfaces of the two portions of the auxiliary electrode SW separated from each other. When the upper surface of the auxiliary electrode SW is covered by the encapsulation layer TFE, measuring the contact resistance between the second electrode 270 and the auxiliary electrode SW may be difficult. However, the display device according to an embodiment of the present invention forms a separate resistance measurement tag to measure the contact resistance between the second electrode 270 and the auxiliary electrode SW.

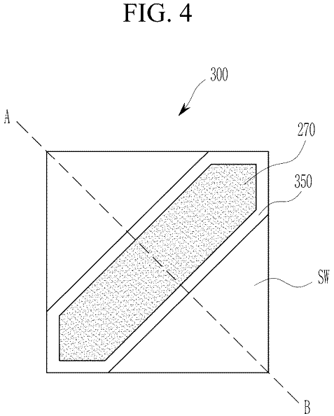

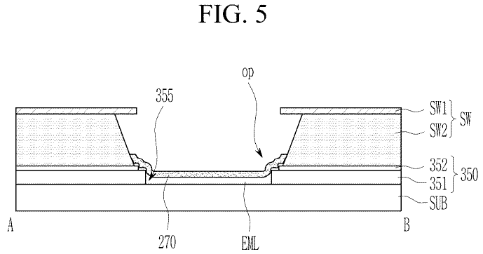

FIG. 4 shows the front of the tag 300 for measuring resistance according to an embodiment of the present invention, and FIG. 5 is a cross-sectional view taken along line A-B of FIG. 4.

Referring to FIGS. 4 and 5, a partition wall 350 including an opening 355 is located on the substrate SUB.

The partition wall 350 may include a first layer 351 and a second layer 352. The first layer 351 may be located between the second layer 352 and the substrate SUB.

The second layer 352 may have a planar area smaller than that of the first layer 351, and as shown in FIG. 5, part of the first layer 351 may not overlap with the second layer 352, and the first layer 351 and the second layer 352 may have a stepped structure.

The light emitting layer EML and the second electrode 270 are located within the opening of the partition wall 350.

An auxiliary electrode SW is located overlapping the partition wall 350, and the auxiliary electrode SW includes a first layer SW1 and a second layer SW2. The second layer SW2 may be located between the first layer SW1 and the partition wall 350. For example, the second layer SW2 may be located between the first layer SW1 and the substrate SUB.

The second electrode 270 is located within the opening OP of the auxiliary electrode SW, and the second electrode 270 is in contact with the auxiliary electrode SW from the side. For example, the second electrode 270 is in contact with the side surface of the auxiliary electrode SW (e.g. the second layer SW2) exposed to the opening OP of the auxiliary electrode SW.

In an embodiment of the present invention, the second electrode 270 of the resistance measurement tag does not contact the first layer SW1 of the auxiliary electrode SW.

The first layer SW1 may have an undercut structure, an may protrude more than the second layer SW2 at the opening OP of the auxiliary electrode SW.

Referring to FIG. 4, the tag for measuring resistance according to an embodiment of the present invention has a structure in which two portions of the auxiliary electrode SW are separated from each other by an opening OP and are connected to each other through the second electrode 270.

Therefore, when measuring resistance on the two upper surfaces of the two portions of the auxiliary electrode SW separated from each other, the contact resistance of the auxiliary electrode SW and the second electrode 270 can be measured.

As shown in FIG. 5, the tag 300 for measuring resistance according to an embodiment of the present invention may not include a first electrode. This is because the resistance measurement tag 300 is not a pixel that emits light, so the first electrode is unnecessary.

However, to measure resistance in a structure similar to an actual light emitting pixel, the resistance measurement tag 300 may include a first electrode.

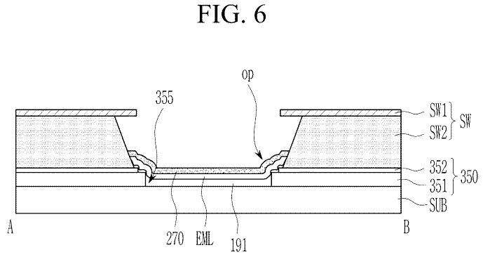

FIG. 6 shows a tag for measuring resistance according to an embodiment of the present invention.

Referring to FIG. 6, the tag for measuring resistance according to an embodiment of the present invention is the same as that of the embodiment of FIG. 5 except that it further includes a first electrode 191. Detailed descriptions of the same components are omitted. As shown in FIG. 6, the tag for measuring resistance according to an embodiment of the present invention may include the first electrode 191, the light emitting layer EML, and the second electrode 270 which together may form a light emitting device LED structure similar to that shown in FIG. 3.

The resistance measurement tag in FIG. 6 has a stacked structure similar to an actual light emitting pixel, and can more accurately measure the contact resistance of the second electrode 270 and the auxiliary electrode SW.

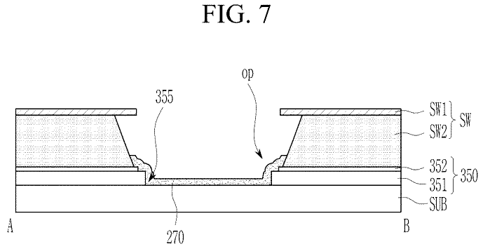

FIG. 7 shows a tag for measuring resistance according to an embodiment of the present invention.

Referring to FIG. 7, the tag for measuring resistance according to an embodiment of the present invention is the same as that of the embodiment of FIG. 5 except that it does not include an emitting layer EML. Detailed descriptions of the same components are omitted.

In the case of FIG. 7, a tag for measuring resistance can be manufactured with a simple structure as it includes only the second electrode 270 and the auxiliary electrode SW.

Since the tag for measuring resistance is not an area where light emission occurs, it does not need to include a first electrode and a light emitting layer, and can measure the contact resistance of the second electrode and the auxiliary electrode. In other words, components or layers except the second electrode and the auxiliary electrode may be selectively eliminated for the tag for measuring resistance according to an embodiment of the present invention. However, the present invention is not limited thereto. For example, besides the second electrode and the auxiliary electrode, other components or layers not interfering the measurement of the contact resistance between the second electrode and the auxiliary electrode may be added to the structure of the tag for measuring resistance.

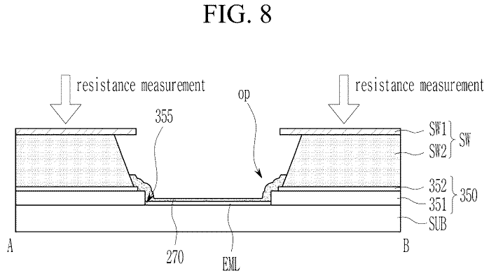

FIG. 8 shows a method of measuring contact resistance using a tag for measuring resistance according to an embodiment of the present invention.

Referring to FIG. 8, the contact resistance between the auxiliary electrode SW and the second electrode 270 can be measured by measuring the resistance on the upper surface of each of the two portions of the auxiliary electrode SW separated from each other by the opening OP.

The shape of the resistance measurement tag 300 shown in FIG. 4 is only an example, and the present invention is not limited thereto. For example, the resistance measurement tag 300 according to an embodiment of the present invention can be modified into various shapes as long as two portions of the auxiliary electrode SW are separated from each other by the opening OP and are connected through the second electrode 270.

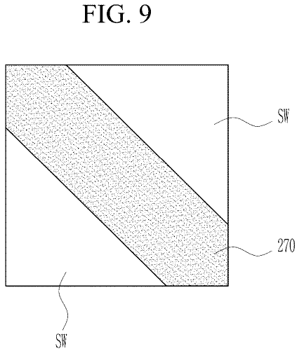

FIG. 9 to FIG. 11 each shows a planar shape of a tag 300 for measuring resistance according to an embodiment of the present invention.

As shown in FIGS. 9 to 11, the planar shape of the resistance measurement tag 300 may vary.

In an embodiment of the present invention, the planar shape of the second electrode 270 of the tag 300 for measuring resistance may be different from the planar shapes of the second electrodes 270 of the red pixel PXR, the green pixel PXG, and the blue pixel PXB. However, the present invention is not limited thereto.

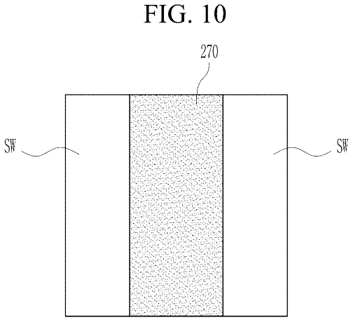

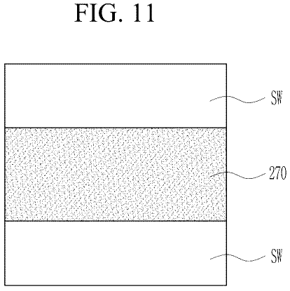

In FIG. 9, the second electrode 270 may be arranged diagonally between two portions of the auxiliary electrode SW to connect the two portions of the auxiliary electrode SW separated from each other. In FIG. 10, the second electrode 270 may be arranged to extend along a vertical axis on a plane between two portions of the auxiliary electrode SW to connect the two portions of the auxiliary electrode SW separated from each other. In FIG. 11, the second electrode 270 may be arranged to extend along a horizontal axis on a plane between two portions of the auxiliary electrode SW to connect the two portions of the auxiliary electrode SW separated from each other.

Structures different from FIGS. 9 to 11 are included in the present invention as long as two portions of the auxiliary electrode SW are separated from each other by the opening OP and connected through the second electrode 270.

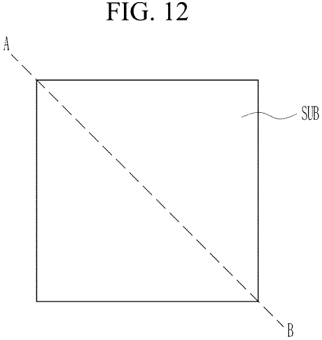

FIG. 12 to FIG. 23 show a method of manufacturing a tag for measuring resistance according to an embodiment of the present invention.

In FIGS. 12 to 23, the even-numbered drawings show a plan view of the manufacturing method, and the odd-numbered drawings show a cross-section cut along the cross-section line of the even-numbered drawings.

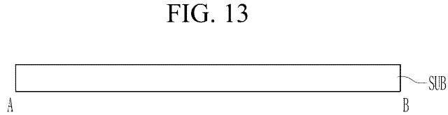

Referring to FIGS. 12 and 13, a substrate SUB is prepared.

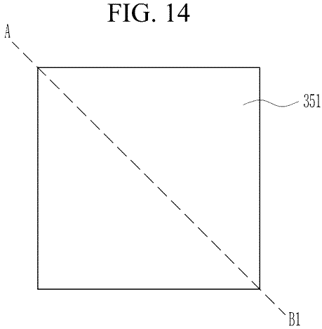

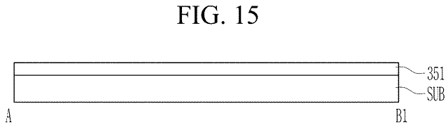

Next, referring to FIGS. 14 and 15, the first layer 351 of the partition wall is formed on the substrate SUB.

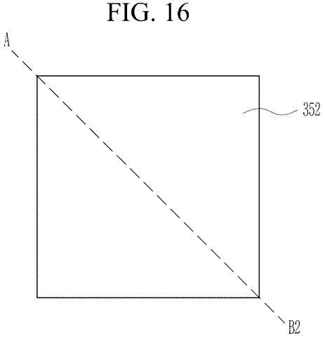

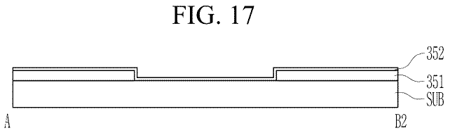

Next, referring to FIGS. 16 and 17, an opening is formed in the first layer 351 of the partition wall 350, and a second layer 352 is conformally formed on the entire surface. For example, the second layer 352 is conformally formed to cover the top surface of the first layer 351, and the side surfaces of the first layer 351 and the top surface of the substrate SUB exposed by the opening formed in the first layer 351.

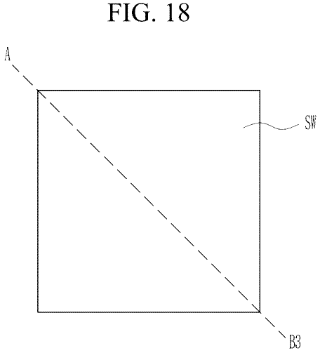

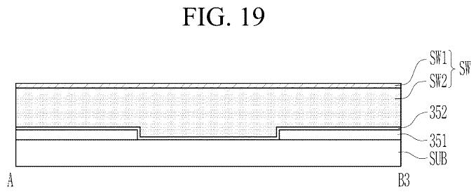

Next, referring to FIGS. 18 and 19, an auxiliary electrode SW is formed.

The auxiliary electrode SW includes a first layer SW1 and a second layer SW2.

The first layer SW1 and the second layer SW2 may include different materials, and etch rates of the first layer SW1 and the second layer SW2 may be different. For example, the second layer SW2 may have etch selectivity with respect to the first layer SW1.

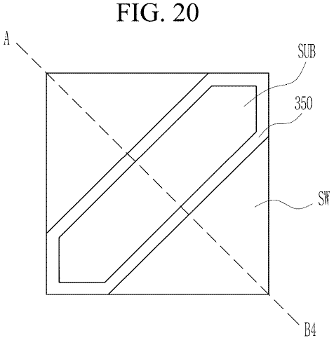

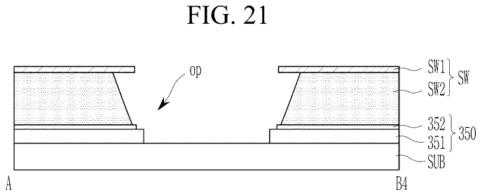

Next, referring to FIGS. 20 and 21, an opening OP of the auxiliary electrode SW is formed.

During this process, the auxiliary electrode SW may be separated into two portions which are not connected to each other.

During the etching process to form the opening OP, each layer may have different etch rate, so the sides of the opening OP do not match, and an undercut structure or step may be formed. For example, the etch rate of the second layer SW2 may be higher than the etch rate of the first layer SW1.

As shown in FIG. 21, the first layer SW1 may have an undercut structure, and may protrude more than the second layer SW2 at the opening OP of the auxiliary electrode SW.

Additionally, a step may be formed between the first layer 351 and the second layer 352 of the partition wall 350. For example, the etch rate of the second layer 352 of the partition wall 350 may be higher than the etch rate of the first layer 351 of the partition wall 350.

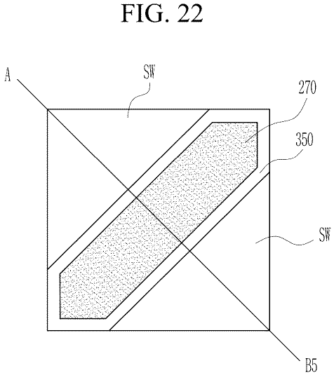

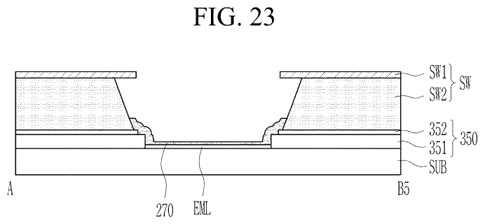

Next, referring to FIGS. 22 and 23, an emission layer EML and a second electrode 270 are formed in the opening OP of the auxiliary electrode SW.

As shown in FIG. 23, the second electrode 270 may contact the auxiliary electrode SW from the side. For example, the second electrode 270 may be in contact with the side surface of the auxiliary electrode SW exposed to the opening OP of the auxiliary electrode SW.

Accordingly, the two portions of the auxiliary electrode SW separated from each other in the previous step may be connected to each other through the second electrode 270.

After manufacturing the tag for resistance measurement in this way, the contact resistance between the auxiliary electrode SW and the second electrode 270 can be measured by measuring the resistance on the upper surfaces of the two portions of the auxiliary electrode SW separated from each other.

As stated above, the resistance measuring tag and the display device including it according to an embodiment of the present invention have a structure in which separate portions of an auxiliary electrode are connected through a second electrode, and the contact resistance between the auxiliary electrode and the second electrode can be measured by measuring the resistance from the upper surfaces of the separate portions of the auxiliary electrode.

Therefore, in a display device in which the second electrodes of the pixels are connected to each other through an auxiliary electrode, the contact resistance between the second electrode and the auxiliary electrode can be accurately measured.

Although the embodiments of the present invention have been described in detail above, the present invention is not limited thereto, and various modifications and enhancements may be made therein by those skilled in the art without departing from the spirit and scope of the present invention as defined in the appended claims.

What is claimed is:

1. A tag for measuring resistance, comprising:
a substrate;
an auxiliary electrode located on the substrate and having two portions spaced apart from each other with an opening in between, and
a second electrode located within the opening,
wherein the auxiliary electrode includes a first layer and a second layer,
the second layer is located between the first layer and the substrate,
some areas of the first layer have an undercut structure, and do not overlap a top surface of the second layer, and
the second electrode contacts the auxiliary electrode from a side of the auxiliary electrode.

2. The tag for measuring resistance of claim 1, wherein
the two portions of the auxiliary electrode spaced apart from each other are electrically connected by the second electrode.

3. The tag for measuring resistance of claim 1, further comprising
a partition wall located on the substrate,
wherein the partition wall includes an opening, and
the second electrode is located within the opening of the partition wall.

4. The tag for measuring resistance of claim 3, wherein
the partition wall includes a first layer and a second layer,
the first layer of the partition wall is located between the second layer of the partition wall and the substrate, and
a portion of the first layer of the partition wall does not overlap the second layer of the partition wall.

5. The tag for measuring resistance of claim 1, further comprising:
a light emitting layer located between the substrate and the second electrode.

6. The tag for measuring resistance of claim 5, further comprising
a first electrode positioned between the substrate and the second electrode.

7. The tag for measuring resistance of claim 1, wherein
the second electrode does not contact the first layer of the auxiliary electrode.

8. The tag for measuring resistance of claim 1, wherein
a contact resistance between the second electrode and the auxiliary electrode is measured on an upper surface of the auxiliary electrode.

9. A display device, comprising:
a substrate including a display area and a non-display area; and
a resistance measurement tag located in the display area or the non-display area,
wherein the resistance measurement tag comprises:
a first auxiliary electrode located on the substrate and having two portions spaced apart from each other with an opening in between; and
a first second electrode located within the opening,
wherein the first auxiliary electrode includes a first layer and a second layer,
the second layer is located between the first layer and the substrate,
some areas of the first layer have an undercut structure, and do not overlap a top surface of the second layer, and
the first second electrode is in contact with the first auxiliary electrode from a side of the first auxiliary electrode.

10. The display device of claim 9, further comprising
a plurality of pixels located in the display area,
wherein one second second electrode is located for each of the pixels, and
two of the second second electrodes respectively located in two adjacent ones of the pixels are electrically connected to each other through a second auxiliary electrode.

11. The display device of claim 10, wherein
in the pixels located in the display area, each of the second second electrodes is in contact with the second auxiliary electrode from a side of the second auxiliary electrode.

12. The display device of claim 10, wherein
in the display area, the second auxiliary electrode includes a first layer and a second layer,
the second layer is located between the first layer and the substrate, and
a portion of the first layer has an undercut structure, and does not overlap a top surface of the second layer.

13. The display device of claim 10, wherein
in the pixels located in the display area, the second auxiliary electrode includes an opening for each of the pixels, and
each of the second second electrodes is located respectively within the opening for each of the pixels.

14. The display device of claim 13, wherein
each of the pixels located in the display area further includes a first encapsulation layer covering the opening, and
each of the first encapsulation layers is positioned separately for each of the pixels.

15. The display device of claim 9, wherein
The two portions of the first auxiliary electrode spaced apart from each other of the resistance measurement tag are electrically connected by the first second electrode.

16. The display device of claim 9, wherein
the resistance measurement tag further includes a partition wall located on the substrate,
the partition wall includes an opening, and
the first second electrode is located within the opening of the partition wall.

17. The display device of claim 16, wherein
the partition wall of the resistance measurement tag includes a first layer and a second layer,
the first layer is located between the second layer and the substrate, and
a portion of the first layer does not overlap the second layer.

18. The display device of claim 9, wherein
the resistance measurement tag further includes a light emitting layer located between the substrate and the first second electrode.

19. The display device of claim 18, wherein
the resistance measurement tag further includes a first electrode positioned between the substrate and the first second electrode.

20. The display device of claim 9, wherein
the first second electrode of the resistance measurement tag does not contact the first layer of the first auxiliary electrode.
